(19) United States
(12) Patent Application Publication
(10) Pub. No.: US 2003/0096466 A1
(43) Pub. Date: May 22, 2003

(54) Method for forming gate dielectrics of varying thicknesses on a wafer

(76) Inventors: Robert H. Eklund, Plano, TX (US); Douglas T. Grider, McKinney, TX (US)

Correspondence Address: TEXAS INSTRUMENTS INCORPORATED, P O BOX 655474, M/S 3999, DALLAS, TX, 75265

(21) Appl. No.: 10/301,105

(22) Filed: Nov. 21, 2002

Related U.S. Application Data
(62) Division of application No. 09/697,925, filed on Oct. 26, 2000.
(60) Provisional application No. 60/172,430, filed on Dec. 17, 1999.

(51) Int. Cl. H01L 21/336; H01L 21/8234

(52) U.S. Cl. 438/197; 438/275

(57) ABSTRACT

A method for forming gate dielectrics of varying thicknesses on a substrate (12) is disclosed that includes providing a substrate (12) having a low voltage section (14) and a high voltage section (18). The high voltage section (18) is operable to support a higher voltage than the low voltage section (14). A first layer (40) is formed outwardly of the substrate (12). A second layer (42) is formed outwardly of the substrate (12). The first layer (40) and the second layer (42) form a thick gate dielectric layer. The thick gate dielectric layer is removed from the low voltage section (14). A thin gate dielectric layer (50) is formed outwardly of the substrate (12) in the low voltage section (14).

### TECHNICAL FIELD OF THE INVENTION

This invention relates generally to electronic circuits and more particularly to a method for forming gate dielectrics of varying thicknesses on a wafer.

### BACKGROUND OF THE INVENTION

Modern electronic equipment such as televisions, telephones, radios and computers are generally constructed of solid state devices. Solid state devices are preferred in electronic equipment because they are extremely small and relatively inexpensive. Additionally, solid state devices are very reliable because they have no moving parts, but are based on the movement of charge carriers.

Solid state devices may be transistors, capacitors, resistors and other semiconductor devices. Typically, such devices are fabricated on and in a substrate and interconnected to form memory arrays, logic structures, timers and other integrated circuits. As more and varied types of devices are included on a substrate of a single wafer, the wafer may need to support different voltage levels corresponding to those devices. This is useful for allowing the wafer to operate at a lower voltage for maximum performance and reduced power requirements while still being able to interface to higher voltages external to the wafer.

A typical wafer requiring different voltage levels for the operation of different devices includes gate dielectrics of different thicknesses. However, conventional methods for forming these gate dielectrics include applying a photoresist mask to cover portions of the wafer, while exposing other portions of the wafer. Gate dielectrics are then formed in the exposed portions that are of a different thickness than those previously formed in the covered portions.

Disadvantages associated with these methods include the enhancement of weaknesses that exist in the gate dielectrics which are covered by the photoresist mask. This is a result of the stripping of the photoresist mask after use and the following clean-up procedures.

### SUMMARY OF THE INVENTION

In accordance with the present invention, a method for forming gate dielectrics of varying thicknesses on a wafer is provided that substantially eliminates or reduces the disadvantages or problems associated with previously developed methods. In particular, the present invention provides a method that allows gate dielectrics of multiple thicknesses to be formed while reducing the defect densities of thicker gate dielectrics.

In one embodiment of the present invention, a method is provided for forming gate dielectrics of varying thicknesses on a substrate. The method includes providing a substrate having a low voltage section and a high voltage section. The high voltage section is operable to support a higher voltage than the low voltage section. A first layer is formed outwardly of the substrate. A second layer is formed outwardly of the substrate. The first layer and the second layer form a thick gate dielectric layer. The thick gate dielectric layer is removed from the low voltage section. A thin gate dielectric layer is formed outwardly of the substrate in the low voltage section.

Technical advantages of the present invention include providing an improved method for forming gate dielectrics of varying thicknesses on a wafer. In particular, a combination of a thermal oxide and a deposited oxide is used to form a thicker layer. Accordingly, most defects within each oxide layer are not aligned with each other. As a result, these defects do not substantially affect performance and thus the defect density of the thick layer is reduced.

Other technical advantages of the present invention will be readily apparent to one skilled in the art from the following figures, descriptions and claims.

### BRIEF DESCRIPTION OF THE DRAWINGS

For a more complete understanding of the present invention and its advantages, reference is now made to the following description taken in conjunction with the accompanying drawings, wherein like reference numerals represent like parts, in which:

FIGS. 1A-F are a series of schematic cross-sectional diagrams illustrating a method for forming gate dielectrics of varying thicknesses on a wafer in accordance with one embodiment of the present invention.

### DETAILED DESCRIPTION OF THE INVENTION

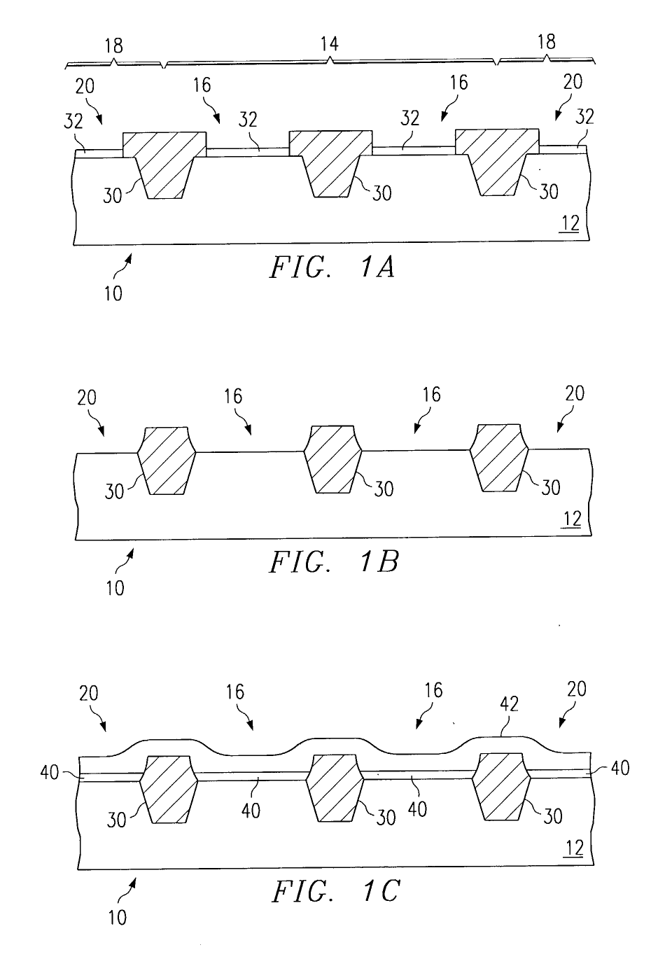

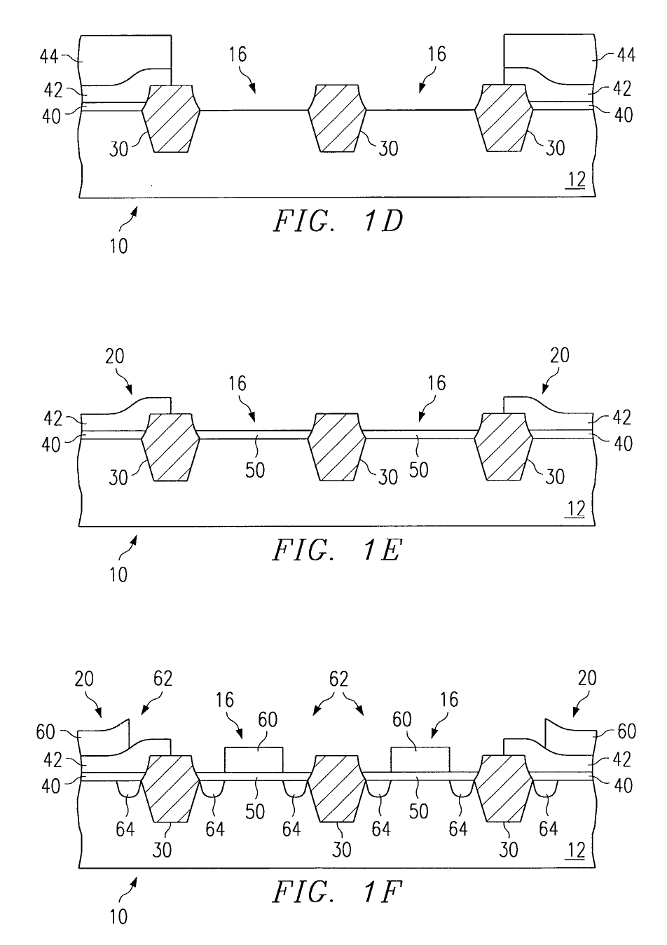

Referring to FIG. 1A, an initial structure 10 for an electronic circuit includes a substrate 12 having one or more low voltage sections 14 with a plurality of thin gate dielectric regions 16 and one or more high voltage sections 18 with a plurality of thick gate dielectric regions 20. The substrate 12 comprises a semiconductor material such as single crystalline silicon. The substrate 12 is a semiconductor wafer, an epitaxial layer grown on a wafer, a semiconductor-on-insulation system or other suitable structure. The gate dielectric regions 16 and 20 may form transistors, capacitors, resistors, or other suitable devices.

For an exemplary embodiment, the structure 10 includes a plurality of isolation structures 30 formed with high density plasma (HDP) oxide, atmospheric-pressure chemical vapor deposition oxide, or other suitable oxide. The isolation structures 30 may be formed by shallow trench isolation, local oxidation of silicon, or any other suitable method. The isolation structures 30 are disposed within and outwardly of the substrate 12.

The structure 10 also includes a disposable gate oxidation layer 32 to allow doping of the substrate 12. For example, if the gate dielectric regions 16 and 20 are used to form transistors, wells and channels for the transistors may be doped in accordance with the desired characteristics of the transistors. The disposable gate oxidation layer 32 is formed with a thermal oxide such as silicon dioxide or any other suitable material that may be selectively removed from the substrate 12 and the isolation structures 30. For the embodiment in which the disposable gate oxidation layer 32 is formed with a thermal oxide, the thermal oxidation may be provided in a furnace, by rapid thermal oxidation, or by any other suitable method. The layer 32 is disposed outwardly of the substrate 12 and allows doping of the substrate 12.

Referring to FIG. 1B, the disposable gate oxidation layer 32 is removed after doping is completed. The gate oxidation layer 32 is preferably removed by an isotropic etch process that is selective to the substrate 12 and the isolation structures 30. This allows the disposable gate oxidation layer 32 to be removed by a blanket process (without masking) without damaging the substrate 12 or the isolation structures 30. As shown in FIG. 1B, however, portions of the isolation structures 30 may be removed with the disposable gate oxidation layer 32 without departing from the scope of the present invention. For the embodiment where the disposable gate oxidation layer 32 comprises silicon dioxide, the substrate 12 comprises silicon, and the isolation structures 30 comprise HDP oxide, this is an etch containing hydrofluoride (HF), such as dil-HF, BOE (HF+NH₄F), or other suitable HF-containing etch.

Referring to FIG. 1C, a thermal oxide layer 40 is formed outwardly of the substrate 12 between the isolation structures 30. The thermal oxide layer 40 may comprise silicon dioxide, an oxynitride, or other suitable material. For the embodiment in which the layer 40 comprises silicon dioxide, the layer 40 is grown by thermal oxidation of silicon or other suitable method. For the embodiment in which the layer 40 is formed by thermal oxidation, the thermal oxidation may be provided in a furnace, by rapid thermal oxidation, or by any other suitable method. The layer 40 may be about 10 to about 100 Å thick depending on the voltages that are to be supported by the high voltage section 18. For higher voltages, the layer 40 is thicker.

A second oxide layer 42 is formed outwardly of the substrate 12. The second oxide layer 42 comprises silicon dioxide or other suitable oxide or oxynitride. The second oxide layer 42 is a conformal layer that is deposited by chemical vapor deposition (CVD) or other suitable method. The layer 42 may be about 20 to about 200 Å thick depending on the voltages that are to be supported by the high voltage section 18. For higher voltages, the layer 42 is thicker. According to one embodiment, the second oxide layer 42 is nitrogen-doped. This is beneficial for applications in which reduced penetration of Boron into the substrate 12 is desirable.

In situations including excess strain between layers 40 and 42 and a second oxide layer 42 comprising low quality silicon dioxide, the structure 10 may be annealed before continuing if a later anneal will not be performed. This anneal serves to densify the second oxide layer 42 and to relieve strain at the interface of the layers 40 and 42. An inert anneal may be used, as well as an oxidizing anneal, an anneal with steam ambients, or any other suitable anneal.

Referring to FIG. 1D, a mask 44 is conventionally formed outwardly of the substrate 12. The mask 44, which comprises a material that is sensitive to light, is patterned through a process that generally includes photolithography and etching. The mask 44 forms a pattern that corresponds to the thin gate dielectric regions 16 on the structure 10. Etching is then used to remove the exposed layers 40 and 42 over the thin gate dielectric regions 16, while the mask 44 provides a protective layer over the remainder of the structure 10.

Thus, the thin gate dielectric regions 16 are exposed, while the thick gate dielectric regions 20 remain protected by the mask 44. The thermal oxide layer 40 and the second oxide layer 42 over the thin gate dielectric regions 16 may then be removed without affecting the layers 40 and 42 over the thick gate dielectric regions 20. The layers 40 and 42 over the thin gate dielectric regions 16 are removed with a wet chemical etch, such as hydrofluoric acid, with a plasma strip, or with any other suitable method.

Referring to FIG. 1E, the photoresist layer 44 is removed and the exposed surface of the substrate 12, which corresponds to the thin gate dielectric regions 16, is prepared for the formation of thin gate dielectrics. This may be accomplished through a pre-gate oxidation clean-up or other suitable method. After removing the photoresist layer 44 and preparing the substrate 12, a thin gate oxidation layer 50 is formed over the thin gate dielectric regions 16 outwardly of the substrate 12. The thin gate oxidation layer 50 is formed by steam, dry, rapid thermal, or other suitable oxidation method, in the presence of an oxide, a nitriding ambient such as nitric oxide or nitrous oxide, or other suitable ambient. With an oxide ambient, an anneal in nitric oxide or nitrous oxide may be utilized to provide nitrogen in the layer 50, if desired. With an oxynitride ambient, a re-oxidation may be performed, if desired. Thus, the thin gate oxidation layer 50 may comprise an oxide, such as silicon dioxide, or an oxynitride depending on the ambient and the anneal, if any. If sufficient anneal is used at this stage in the process so as to provide beneficial effects to layers 40 and 42 as described above in connection with FIG. 1C, no anneal is required prior to forming the photoresist layer 44. The layer 50 may be about 10 to about 50 Å thick depending on the voltages that are to be supported by the low voltage section 14. For higher voltages, the layer 50 is thicker.

Referring to FIG. 1F, a polysilicon layer (not shown) is formed outwardly of the substrate 12. The polysilicon layer comprises polysilicon, amorphous silicon, or other suitable gate material. The polysilicon layer is a conformal layer that is deposited by Low Pressure CVD, Rapid Thermal CVD, or other suitable method. The polysilicon layer may be about 1,200 to about 2,500 Å thick. At this stage of the process, the polysilicon layer may be patterned and etched to define gates, sources, drains, or other suitable conductive features on the structure 10. For example, standard CMOS processing through metallization may be performed at this stage.

According to the embodiment shown in FIG. 1F, the polysilicon layer is patterned and etched to form gates 60 for transistors 62. Sources and drains 64 may also be formed at this stage of the process. After formation of the gates 60 and sources/drains 64, gate contacts and source/drain contacts (not shown) are formed for the transistors 62 in accordance with conventional integrated circuit fabrication techniques.

Thus, the method provides thin gate dielectric regions 16, which include the thin gate oxidation layer 50, and thick gate dielectric regions 20, which include the thermal oxide layer 40 and the second oxide layer 42. This provides for two gate oxide thicknesses on the same structure 10, while also providing a relatively low defect density in the thick gate dielectric regions 20 due to the multiple layers 40 and 42 which form those regions 20. In addition, the two different thicknesses provided by this method allow transistors, or other suitable devices, to be optimized by providing for two different voltage ranges on the same structure 10.

Additionally, the process may be repeated in order to provide three or more gate oxide thicknesses. For example, after the thin gate oxidation layer 50 is formed, a conformal additional gate oxidation layer may be formed outwardly of the substrate 12. The process may then continue as previously described, with the photoresist layer 44 remaining over the thin gate dielectric regions 16, which include the thin gate oxidation layer 50 and the additional gate oxidation layer, and over the thick gate dielectric regions 20, which include the thermal oxide layer 40, the second oxide layer 42 and the additional gate oxidation layer.

The exposed portions may then be processed in accordance with the process described above for the thin gate dielectric regions 16 in order to form gate dielectric regions with thicknesses less than either the thin gate dielectric regions 16 or the thick gate dielectric regions 20. As previously described, the thin gate dielectric regions 16 and the thick gate dielectric regions 20 in this embodiment have a relatively low defect density due to the multiple layers which form those regions 16 and 20. In addition, the three different thicknesses provided by this method allow transistors, or other suitable devices, to be optimized by providing for three different voltage ranges on the same structure 10.

Although the present invention has been described with several embodiments, various changes and modifications may be suggested to one skilled in the art. It is intended that the present invention encompass such changes and modifications as fall within the scope of the appended claims.

What is claimed is:

1. A method for forming gate dielectrics of varying thicknesses on a substrate, comprising:
providing a substrate having a low voltage section and a high voltage section, the high voltage section operable to support a higher voltage than the low voltage section;
forming a first layer outwardly of the substrate;
forming a second layer outwardly of the substrate, the first layer and the second layer forming a thick gate dielectric layer;
removing the thick gate dielectric layer from the low voltage section; and
forming a thin gate dielectric layer outwardly of the substrate in the low voltage section.

2. The method of claim 1, wherein forming a first layer comprises growing a thermal oxide layer by thermal oxidation of silicon.

3. The method of claim 1, wherein the first layer is about 10 Å to about 100 Å thick.

4. The method of claim 1, wherein the first layer comprises silicon dioxide.

5. The method of claim 1, wherein forming a second layer comprises depositing a conformal layer of silicon dioxide by chemical vapor deposition.

6. The method of claim 1, wherein the second layer is about 20 Å to about 200 Å thick.

7. The method of claim 1, wherein the second layer is nitrogen-doped.

8. The method of claim 1, removing the thick gate dielectric layer comprising:
forming a mask exposing the low voltage section; and
removing the thick gate dielectric layer with a hydrofluoric acid etch.

9. The method of claim 1, forming a thin gate dielectric layer comprising forming the thin gate dielectric layer by oxidation.

10. The method of claim 9, forming a thin gate dielectric layer further comprising forming the thin gate dielectric layer in the presence of a nitriding ambient.

11. The method of claim 1, wherein the thin gate dielectric layer comprises silicon dioxide.

12. The method of claim 1, wherein the thin gate dielectric layer is about 10 Å to about 50 Å thick.

13. A method for forming gate dielectrics of varying thicknesses on a substrate, comprising:
providing a substrate having a low voltage section, an intermediate voltage section, and a high voltage section, the high voltage section operable to support a higher voltage than the intermediate voltage section and the intermediate voltage section operable to support a higher voltage than the low voltage section;
forming a first layer outwardly of the substrate;
forming a second layer outwardly of the substrate;
removing the first layer and the second layer from the low voltage section and the intermediate voltage section;
forming a third layer outwardly of the substrate in the low voltage section and the intermediate voltage section;
forming a fourth layer outwardly of the substrate, the first layer, the second layer and the fourth layer forming a thick gate dielectric layer and the third layer and the fourth layer forming an intermediate gate dielectric layer;
removing the intermediate gate dielectric layer from the low voltage section; and
forming a thin gate dielectric layer outwardly of the substrate in the low voltage section.

14. The method of claim 13, wherein forming a first layer comprises growing a thermal oxide layer by thermal oxidation of silicon.

15. The method of claim 13, wherein forming a second layer comprises depositing a conformal layer of silicon dioxide by chemical vapor deposition.

16. The method of claim 13, forming a thin gate dielectric layer comprising forming the thin gate dielectric layer by oxidation.

17. The method of claim 13, wherein the thin gate dielectric layer comprises silicon dioxide.

18. An integrated circuit, comprising:
a first transistor comprising a thin gate dielectric layer; and
a second transistor adjacent to the first transistor, the second transistor comprising a thick gate dielectric layer, the thick gate dielectric layer thicker than the thin gate dielectric layer and comprising a plurality of independently formed sub-layers.

19. The integrated circuit of claim 18, the thick gate dielectric layer comprising a first sub-layer and a second sub-layer, the first sub-layer comprising silicon dioxide formed by thermal oxidation of silicon and the second sub-layer comprising silicon dioxide formed by chemical vapor deposition.

20. The integrated circuit of claim 18, further comprising a third transistor comprising an intermediate gate dielectric layer, the intermediate gate dielectric layer thicker than the thin gate dielectric layer and thinner than the thick gate dielectric layer, the intermediate gate dielectric layer comprising a plurality of independently formed sub-layers.

21. An integrated circuit, comprising:
a substrate comprising a high voltage section; and
a high voltage device formed outwardly of the substrate in the high voltage section, the high voltage device comprising a thick gate dielectric layer, the thick gate dielectric layer comprising a plurality of independently formed sub-layers.

22. The integrated circuit of claim 21, the thick gate dielectric layer comprising a first sub-layer and a second sub-layer, the first sub-layer comprising silicon dioxide formed by thermal oxidation of silicon and the second sub-layer comprising silicon dioxide formed by chemical vapor deposition.

23. The integrated circuit of claim 21, the substrate further comprising a low voltage section, the circuit further comprising a low voltage device formed outwardly of the substrate in the low voltage section, the low voltage device comprising a thin gate dielectric layer, the thin gate dielectric layer thinner than the thick gate dielectric layer.

24. The integrated circuit of claim 23, the substrate further comprising an intermediate voltage section, the circuit further comprising an intermediate voltage device formed outwardly of the substrate in the intermediate voltage section, the intermediate voltage device comprising an intermediate gate dielectric layer, the intermediate gate dielectric layer thinner than the thick gate dielectric layer and thicker than the thin gate dielectric layer.
